(19) United States
(12) Patent Application Publication
(10) Pub. No.: US 2026/0188157 A1
(43) Pub. Date: Jul. 2, 2026

(54) Display Device and Method of Repairing the Same

(71) Applicant: LG Display Co., Ltd., Seoul (KR)

(72) Inventors: Soon Hwan Hong, Paju-si (KR); Chang Soo Kim, Paju-si (KR); Hong Sik Kim, Paju-si (KR)

(21) Appl. No.: 19/435,322

(22) Filed: Dec. 29, 2025

(30) Foreign Application Priority Data
Dec. 31, 2024 (KR) 10-2024-0203035

(51) Int. Cl. G09G 3/00; G09G 3/3233

(52) U.S. Cl. CPC G09G 3/006; G09G 3/3233; G09G 2300/0413; G09G 2300/0426; G09G 2330/10; G09G 2330/12

(57) ABSTRACT

A display device includes a plurality of light emitting pixels provided in a light emitting region of a display panel and including a light emitting element and a light emitting pixel circuit for driving the light emitting element, and a plurality of dummy pixels provided in a dummy area around the light emitting region and including a dummy pixel circuit and a dummy light emitting element, the dummy pixel circuit configured to generate a driving current by receiving a data voltage supplied to a defective pixel among the light emitting pixels, and the dummy pixels configured to supply the generated driving current to a light emitting element of the defective pixel, wherein the plurality of dummy pixels includes a long-distance compensation dummy pixel including a compensation structure that compensates for capacitance according to a separation distance from the defective pixel when the separation distance is greater than a reference distance.

### CROSS-REFERENCE TO RELATED APPLICATION

This application claims the benefit of Republic of Korea Patent Application No. 10-2024-0203035, filed on Dec. 31, 2024, which is hereby incorporated by reference.

### BACKGROUND OF THE DISCLOSURE

### Field of the Disclosure

The present disclosure relates to a display device and a method of repairing the same.

### Discussion of the Related Art

An electroluminescent display device may display an image by including a plurality of subpixels and having a light emitting element of each subpixel emit light. The light emitting element may be implemented based on an organic or inorganic material.

The subpixel of the electroluminescent display device includes a light emitting element and a pixel circuit for driving the light emitting element. The pixel circuit may display an image by controlling a driving current applied to the light emitting element.

In such a display device, in a process of manufacturing the light emitting element and the pixel circuit, a defect in which a pixel does not normally operate may occur due to deterioration of characteristics of a thin film transistor (TFT) and occurrence of short circuit between lines and layers.

### SUMMARY OF THE DISCLOSURE

Accordingly, the present disclosure is directed to a display device and a method of repairing the same that substantially obviate one or more problems due to limitations and disadvantages of the related art.

Embodiments disclosed in the present disclosure are intended to solve the above-mentioned problem, and to provide a display device and a method of repairing the same capable of increasing production yield and mitigating quality deterioration by repairing a defective subpixel.

Additional advantages, objects, and features of the disclosure will be set forth in part in the description which follows and in part will become apparent to those having ordinary skill in the art upon examination of the following or may be learned from practice of the disclosure. The objectives and other advantages of the disclosure may be realized and attained by the structure particularly pointed out in the written description and claims hereof as well as the appended drawings.

To achieve these objects and other advantages and in accordance with the purpose of the disclosure, as embodied and broadly described herein, a display device includes a plurality of light emitting pixels provided in a light emitting region of a display panel and including a light emitting element and a light emitting pixel circuit for driving the light emitting element, and a plurality of dummy pixels provided in a dummy area around the light emitting region and including a dummy pixel circuit and a dummy light emitting element, the dummy pixel circuit configured to generate a driving current by receiving a data voltage supplied to a defective pixel among the light emitting pixels, and configured to supply the generated driving current to a light emitting element of the defective pixel, wherein the plurality of dummy pixels includes a long-distance compensation dummy pixel including a compensation structure that compensates for capacitance according to a separation distance from the defective pixel when the separation distance is greater than a reference distance.

The display device may further include a first dummy pixel that is connected when the separation distance from the defective pixel is less than or equal to the reference distance, wherein the first dummy pixel may include a dummy pixel circuit having the same circuit configuration as a circuit configuration of the light emitting pixel circuit.

The dummy pixel circuit of the long-distance compensation dummy pixel may include a capacitor in which the data voltage is stored, and a driving transistor configured to generate the driving current according to the data voltage stored in the capacitor, and the driving transistor of the long-distance compensation dummy pixel may generate a driving current greater than a driving current generated by the light emitting pixel circuit.

At least one of a channel width or a channel length of the driving transistor of the long-distance compensation dummy pixel may be different from a channel width or a channel length of a driving transistor included in the light emitting pixel circuit.

The display device may include a first low-potential voltage supply wire formed to extend in a second direction in an upper region of the display panel, a second low-potential voltage supply wire formed to extend in the second direction in a lower region of the display panel, and a plurality of low-potential voltage internalized wires formed by extending in a first direction in the light emitting region and the dummy area, each of the low-potential voltage internalized wires having one end connected to the first low-potential voltage supply wire and the other end connected to the second low-potential voltage supply wire, wherein any one of the plurality of low-potential voltage internalized wires may be electrically separated from the first low-potential voltage supply wire and the second low-potential voltage supply wire and used as a repair wire that electrically interconnects the defective pixel and the dummy pixel.

The repair wire may have one end to which an anode of the dummy pixel is connected and the other end to which an anode of the defective pixel is connected.

The display device may further include a compensation capacitor having a first electrode connected to the repair wire and a second electrode connected to a low-potential voltage.

The compensation capacitor may have capacitance set according to a distance between the dummy pixel and the defective pixel.

The plurality of low-potential voltage internalized wires are disposed in the same direction as a plurality of data lines that transmit the data voltage.

The plurality of low-potential voltage internalized wires includes at least one cutting point.

A wire that includes the at least one cutting point among the plurality of low-potential voltage internalized wires is provided with the driving current.

In another aspect of the present disclosure, a method of repairing the display device includes connecting the long-distance compensation dummy pixel when a separation distance from the defective pixel is long.

The display device may include a first low-potential voltage supply wire formed to extend in a second direction in an upper region of the display panel, a second low-potential voltage supply wire formed to extend in the second direction in a lower region of the display panel, and a plurality of low-potential voltage internalized wires formed by extending in a first direction in the light emitting region and the dummy area, each of the low-potential voltage internalized wires having one end connected to the first low-potential voltage supply wire and the other end connected to the second low-potential voltage supply wire, and the method may further include preparing a repair wire by electrically isolating one of the low-potential voltage internalized wires adjacent to the defective pixel from the first low-potential voltage supply wire and the second low-potential voltage supply wire, connecting one end of the repair wire to an anode of a dummy pixel, and connecting the other end of the repair wire to an anode of the defective pixel.

The method may further include a compensation capacitor having a first electrode connected to the repair wire and a second electrode connected to a low-potential voltage.

At least one of a channel width or a channel length of a driving transistor of the long-distance compensation dummy pixel may be different from a channel width or a channel length of a driving transistor included in the light emitting pixel circuit.

It is to be understood that both the foregoing general description and the following detailed description of the present disclosure are exemplary and explanatory and are intended to provide further explanation of the disclosure as claimed.

### BRIEF DESCRIPTION OF THE DRAWINGS

The accompanying drawings, which are included to provide a further understanding of the disclosure and are incorporated in and constitute a part of this application, illustrate embodiment(s) of the disclosure and together with the description serve to explain the principle of the disclosure. In the drawings:

FIG. 1 is a schematic block diagram of a display device according to an embodiment of the present disclosure;

FIG. 2 is a schematic configuration diagram of a subpixel included in the display device of FIG. 1;

FIG. 3 is a circuit diagram illustrating an embodiment of the subpixel included in the display device of FIG. 1;

FIG. 4 is a diagram for describing a configuration of a display panel of the display device according to an embodiment of the present disclosure;

FIG. 5 is a diagram for describing a repair method for a pixel defect (PD) of the display device according to an embodiment of the present disclosure;

FIG. 6 is a diagram for describing a dummy pixel of a display device and a repair method using the same according to a first embodiment of the present disclosure;

FIG. 7 is a diagram for describing a dummy pixel of a display device and a repair method using the same according to a second embodiment of the present disclosure;

FIG. 8 is a diagram for describing a dummy pixel of a display device and a repair method using the same according to a third embodiment of the present disclosure;

FIG. 9 is an exemplary diagram for describing a structure of a dummy area of a display device according to an embodiment of the present disclosure; and

FIG. 10 is a drawing for a repair method for a line defect (LD) of a display device according to an embodiment of the present disclosure.

### DETAILED DESCRIPTION OF THE DISCLOSURE

Advantages and features of the present disclosure and a method of achieving the advantages and features will become clear with reference to the embodiments described in detail below together with the accompanying drawings. However, the present disclosure is not limited to the embodiments disclosed below and may be implemented in various different forms, and the present embodiments are provided only to make the disclosure of the present disclosure complete and to fully inform a person having ordinary skill in the art to which the present disclosure pertain of the scope of the invention.

The shapes, sizes, ratios, angles, numbers, etc. disclosed in the drawings to describe the embodiments of the present disclosure are illustrative, and thus the present disclosure is not limited to the illustrated matters. The same reference numerals refer to the same components throughout the specification. When the terms “include”, “have”, and “consist of”, etc. are used in the present disclosure, other parts may be added unless “only” is used. When a component is expressed in a singular form, this includes the case where the component is plural unless there is a specifically explicit description.

When interpreting a component, the component is interpreted as including an error range even if there is no separate explicit description.

When describing a positional relationship, for example, when a positional relationship between two parts is described as “on”, “above”, “below”, “next to”, etc., one or more other parts may be located between the two parts, unless “immediately” or “directly” is used.

Even though the terms first, second, etc. may be used to describe various components, these components are not limited by these terms. These terms are only used to distinguish one component from another. Thus, a first component mentioned below may be a second component within the technical concept of the present disclosure.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impact, noise, etc.) even when a relevant description is not specified. Further, the term “may” fully encompasses all the meanings of the term “can”.

In describing a temporal relationship, when the temporal order is described as, for example, “after,” “subsequent,” “next,” and “before,” a case that is not continuous may be included unless a more limiting term, such as “just,” “immediate(ly),” or “direct(ly)” is used.

When describing quantitative or numerical relationships, terms such as “equal” and “the same” generally denote “substantially equal” and “substantially the same”, or “similar or equal” and “similar or the same”. That is, on the basis of that two elements being equal or the same, a certain error range is permitted, such as one percent, five percent, ten percent, etc.

In addition, a pixel circuit and a gate driver of a display device described below may include a plurality of transistors. The transistors may be implemented as an oxide thin film transistor (TFT) including an oxide semiconductor, an LTPS TFT including low temperature poly silicon (LTPS), etc. Each of the transistors may be implemented as a p-channel TFT or an n-channel TFT.

A transistor is a three-electrode device that includes a gate, a source, and a drain. The source is an electrode that supplies carriers to the transistor. Inside the transistor, carriers start to flow from the source. The drain is an electrode through which carriers exit the transistor. In the transistor, carriers flow from the source to the drain. In the case of an n-channel transistor, since the carriers are electrons, a source voltage is lower than a drain voltage so that electrons may flow from the source to the drain. In the n-channel transistor, current flows in a direction from the drain to the source. In the case of a p-channel transistor (PMOS), since the carriers are holes, the source voltage is higher than the drain voltage so that the holes may flow from the source to the drain. In the p-channel transistor, since holes flow from the source to the drain, current flows from the source to the drain. It should be noted that the source and the drain of the transistor are not fixed. For example, the source and the drain may be changed depending on the applied voltage. Therefore, the disclosure is not limited by the source and the drain of the transistor. In the following description, the source and the drain of the transistor will be referred to as first and second electrodes.

A gate signal swings between a gate-on-voltage and a gate-off-voltage. The gate-on-voltage is set to a voltage higher than a threshold voltage of the transistor, and the gate-off-voltage is set to a voltage lower than the threshold voltage of the transistor. The transistor turns on in response to the gate-on-voltage, and turns off in response to the gate-off-voltage. In the n-channel transistor, the gate-on-voltage may be a gate-high-voltage (VGH), and the gate-off-voltage may be a gate-low-voltage (VGL). In the p-channel transistor, the gate-on-voltage may be a VGL, and the gate-off-voltage may be a VGH.

Each pixel of an electroluminescent display device includes a light emitting element and a driving element that generates pixel current according to a voltage between a gate and a source to drive the light emitting element. The light emitting element includes an anode, a cathode, and an organic compound layer formed therebetween. The organic compound layer may include, but is not limited to, a hole injection layer (HIL), a hole transport layer (HTL), an emission layer (EML), an electron transport layer (ETL), an electron injection layer (EIL), etc. When a pixel current flows in the light emitting element, holes passing through the HTL and electrons passing through the ETL move to the EML, thereby forming excitons, and as a result, the EML may emit visible light.

The display device according to the present disclosure may be implemented as a television, a video player, a personal computer (PC), a home theater, an automobile electrical device, a smartphone, etc., but the present disclosure is not limited thereto.

Throughout the specification, the same reference numerals refer to substantially the same components. Hereinafter, embodiments of the present disclosure will be described in detail with reference to the attached drawings. In the following description, when it is determined that a detailed description of a known function or configuration related to the present disclosure may unnecessarily obscure the gist of the present disclosure, the detailed description will be omitted.

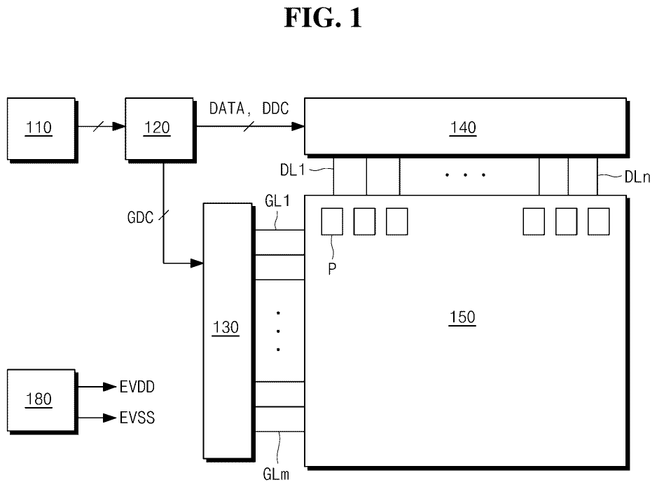

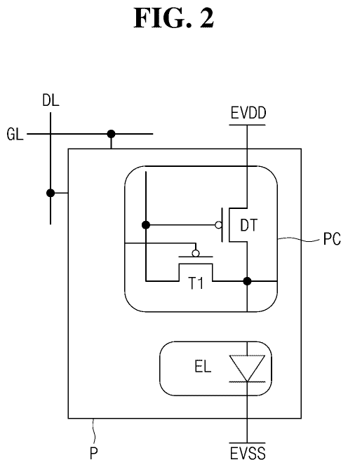

FIG. 1 is a schematic block diagram of a display device according to an embodiment of the present disclosure, and FIG. 2 is a configuration diagram schematically illustrating a subpixel P illustrated in FIG. 1.

Referring to FIGS. 1 and 2, the display device may include an image supply unit 110, a timing controller 120, a scan driver 130, a data driver 140, a display panel 150, a power supply 180, etc.

An image supply unit (set or host system) 110 may supply a data signal supplied from the outside or a data signal and various driving signals stored in an internal memory to the timing controller 120.

The timing controller 120 may output a gate timing control signal GDC for controlling the operation timing of the scan driver 130, a data timing control signal DDC for controlling the operation timing of the data driver 140, various synchronization signals (Vsync, which is a vertical synchronization signal, and Hsync, which is a horizontal synchronization signal), etc. The timing controller 120 may supply a data signal DATA supplied from the image supply unit 110 together with the data timing control signal DDC to the data driver 140. The timing controller 120 may be formed as an IC (Integrated Circuit) and mounted on a printed circuit board, but the present disclosure is not limited thereto.

The scan driver 130 may output a scan signal (or scan voltage) in response to the gate timing control signal GDC supplied from the timing controller 120. The scan driver 130 may supply the scan signal to pixels P included in the display panel 150 through gate lines GL1 to GLm. The scan driver 130 may be formed as an IC or directly formed on the display panel 150 in a gate-in-panel (GIP) manner, but the present disclosure is not limited thereto.

The data driver 140 may sample and latch the data signal DATA in response to the data timing control signal DDC supplied from the timing controller 120, convert a digital data signal into an analog data voltage based on a gamma reference voltage, and output the analog data voltage. The data driver 140 may supply a data voltage to the pixels P included in the display panel 150 through data lines DL1 to DLn. The data driver 140 may be formed as an IC and mounted on the display panel 150 or on a printed circuit board, but the present disclosure is not limited thereto.

The power supply 180 may generate high-potential first power and low-potential second power based on an external input voltage supplied from the outside, and output the power through a high-potential power line EVDD and a low-potential power line EVSS. The power supply 180 may generate not only the first power and the second power, but also a voltage required for driving the scan driver 130 (e.g., a gate voltage including a gate high voltage and a gate low voltage) or a voltage required for driving the data driver 140 (a drain voltage and a half-drain voltage including a drain voltage).

The display panel 150 may display an image in response to a driving signal including a scan signal and a data voltage, the first power, the second power, etc. The pixels P of the display panel 150 directly emit light. The display panel 150 may be manufactured based on a rigid or flexible substrate such as glass, silicon, polyimide, etc.

Referring to FIG. 2, one pixel P may be connected to a data line DL, a gate line GL, the first power line EVDD, and the second power line EVSS. This pixel P may include a light emitting element EL and a pixel circuit PC for driving the light emitting element EL.

The pixel circuit PC may include one or more switching transistors T1 and a driving transistor DT. The one or more switching transistors T1 may be controlled by a scan signal input to the gate line GL, and the driving transistor DT may generate a driving current for driving the light emitting element EL according to a data voltage input to the data line DL. The pixel circuit PC may be implemented in various forms, including the light emitting element EL that emits light, as well as a compensation circuit that compensates for deterioration of the driving transistor DT, etc.

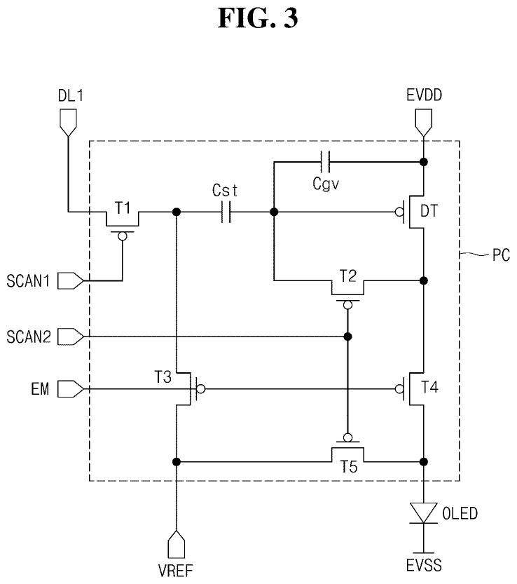

FIG. 3 is a circuit diagram illustrating a pixel circuit PC including six transistors and two capacitors (6T2C) for driving a light emitting diode OLED, which is the light emitting element EL, among various forms of pixels.

A pixel according to an embodiment may include five switching transistors T1 to T5, one driving transistor DT, one storage capacitor Cst, and one light emitting diode OLED. Cgv may be a compensation capacitor provided for compensation, which may be omitted.

The first switching transistor T1 may serve to transmit a data voltage applied through the first data line DL1 to one end of the storage capacitor Cst in response to a first scan signal applied through a first scan line SCAN1.

The second switching transistor T2 may serve to electrically connect a gate electrode and a second electrode of the driving transistor DT in response to a second scan signal applied through a second scan line SCAN2 (serve to put the driving transistor DT in a diode connection state for threshold voltage compensation).

The third switching transistor T3 may serve to transmit a reference voltage applied through a reference line VREF to the one end of the storage capacitor Cst in response to an emission control signal applied through an emission control line EM.

The fourth switching transistor T4 may serve to transmit the driving current generated from the driving transistor DT to an anode of the light emitting diode OLED in response to the emission control signal applied through the emission control line EM.

The storage capacitor Cst may store a data voltage and perform a function of driving the driving transistor DT based on the stored data voltage. The light emitting diode OLED may serve to emit light based on the driving current generated from the driving transistor DT.

The pixel illustrated in FIG. 3 is merely illustrated and described to aid understanding of an operation of the pixel emitting light by the data voltage in connection with the following embodiment, and the present disclosure is not limited thereto.

Meanwhile, when a short circuit occurs in the pixel circuit PC or a defect occurs in a transistor such as the driving transistor DT, a pixel defect may occur in which the light emitting diode OLED emits light or turns off regardless of the data voltage. In order to normalize the operation of such a defective pixel, dummy pixels may be provided in the display panel.

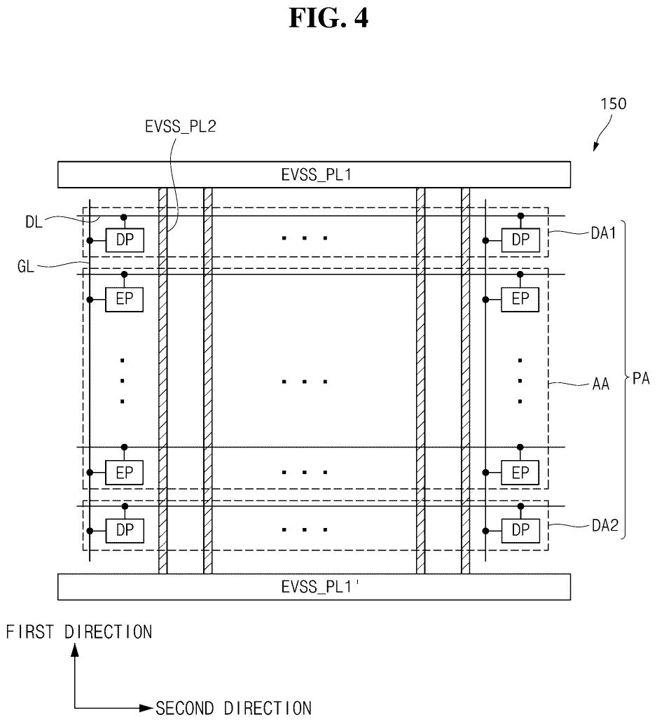

FIG. 4 is a drawing for describing a configuration of the display panel 150 of the display device according to an embodiment of the present disclosure.

Referring to FIG. 4, a pixel array PA formed on the display panel 150 may include an active area AA and a dummy area DA around the active area AA. The dummy area DA may be formed in at least one of upper and lower areas of the active area AA. In the active area AA, a plurality of light emitting pixels EP connected to the gate line GL and the data line DL is arranged, and in the dummy area DA, a plurality of dummy pixels DP connected to the gate line GL and the data line DL is arranged.

The dummy area DA may be formed in at least one portion in a first direction or a second direction of the active area AA. Accordingly, at least one dummy pixel DP may be formed in at least one area of upper and lower portions of a pixel column for each pixel column, or at least one dummy pixel DP may be formed in at least one area of left and right portions of a pixel row for each pixel row. FIG. 4 illustrates a first dummy area DA1 formed in an upper portion of the active area AA and a second dummy area DA2 formed in a lower portion thereof. However, this may be similarly applied when dummy pixels DP are formed in pixel rows of left and right dummy areas DA of the active area AA.

Low-potential voltage supply wires EVSS_PL1 and EVSS_PL1′ that supply a low-potential voltage to the cathode of the light emitting element EL may be formed in the upper and lower portions of the pixel array PA. In a region of the pixel array PA, a plurality of low-potential voltage internalized wires EVSS_PL2 connected to the upper and lower low-potential voltage supply wires EVSS_PL1 and EVSS_PL1′ may be formed.

The low-potential voltage supply wires EVSS_PL1 and EVSS_PL1′ may be formed to extend in the second direction, which is a heat line direction, with a relatively wide width. A low-potential voltage internalized wire EVSS_PL2 is formed to extend in the first direction in the region of the pixel array PA, such that one end is connected to an upper low-potential voltage supply wire EVSS_PL1 and the other end is connected to a lower low-potential voltage supply wire EVSS_PL1′. Accordingly, the low-potential voltage applied to at least one of the low-potential voltage supply wires EVSS_PL1 and EVSS_PL1′ may be transmitted to the low-potential voltage supply wires EVSS_PL1 and EVSS_PL1′ on the other side through the plurality of low-potential voltage internalized wires EVSS_PL2. For example, a low-potential driving voltage applied to the upper low-potential voltage supply wire EVSS_PL1 may be transmitted downward through the low-potential voltage internalized wires EVSS_PL2 formed in the region of the pixel array PA and supplied to the lower low-potential voltage supply wire EVSS_PL1′. Accordingly, it is possible to reduce or prevent occurrence of voltage deviation by position of the low-potential driving voltage in the active area AA (i.e., occurrence of a low-potential driving voltage increase deviation by position).

The low-voltage internalized wire EVSS_PL2 formed in the region of the pixel array PA extends in the second direction without separate contact. Therefore, the low-voltage internalized wire EVSS_PL2 may be used as a repair wire that connects a dummy pixel DP formed at the top or bottom and a defective light emitting pixel EP.

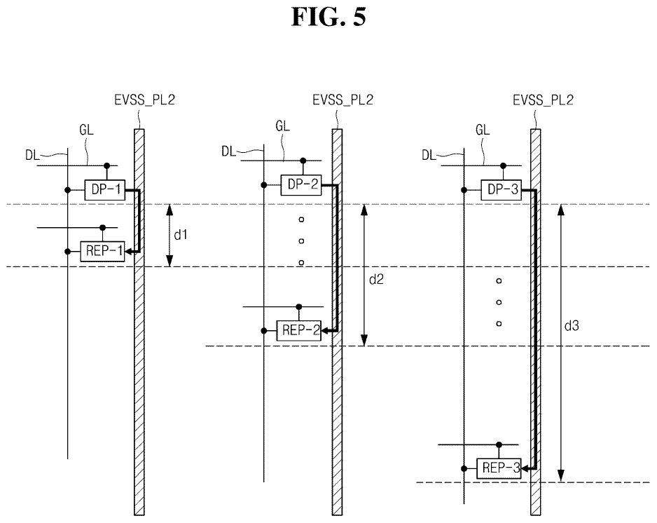

FIG. 5 is a diagram for describing a repair method for a pixel defect of the display device according to an embodiment of the present disclosure.

When a defect occurs in a light emitting pixel EP, a dummy pixel DP at the top or bottom is connected using the low-voltage internalized wire EVSS_PL2 adjacent to the defective light emitting pixel EP, and a driving current is generated from the dummy pixel DP and supplied to the defective light emitting pixel EP, thereby repair-driving the defective light emitting pixel EP. In the following description, a pixel that receives a driving current from a dummy pixel DP and is repair-driven is referred to as a repair pixel REP.

The dummy pixel DP receives the same or substantially same data voltage as a data voltage input to the repair pixel REP. The dummy pixel DP generates a driving current according to the input data voltage, and the driving current generated from the dummy pixel DP is applied to the repair pixel REP through the low-potential voltage internalized wire EVSS_PL2. Accordingly, the defective pixel may be repaired and normally operated.

Meanwhile, depending on the location of the repair pixel REP, a distance between the dummy pixel DP and the repair pixel REP may vary from a first distance to a third distance (d1 to d3). Depending on the distance between the dummy pixel DP and the repair pixel REP, resistor-capacitor RC characteristics between the two pixels may vary. As the distance between the dummy pixel DP and the repair pixel REP increases from the first distance to the third distance d1<d2<d3, resistance and capacitance increase, so that capacitance affecting an anode of a light emitting element of the repair pixel REP may increase. Accordingly, even when the same or substantially same driving current is applied to the dummy pixel DP, luminance reproduced may differ depending on the distance of the repair pixel REP.

Accordingly, the display device according to the embodiment of the present disclosure may compensate for the resistance-capacitor RC characteristic between the two pixels by connecting dummy pixels DP having different electrical characteristics depending on the distance between the dummy pixel DP and the repair pixel REP.

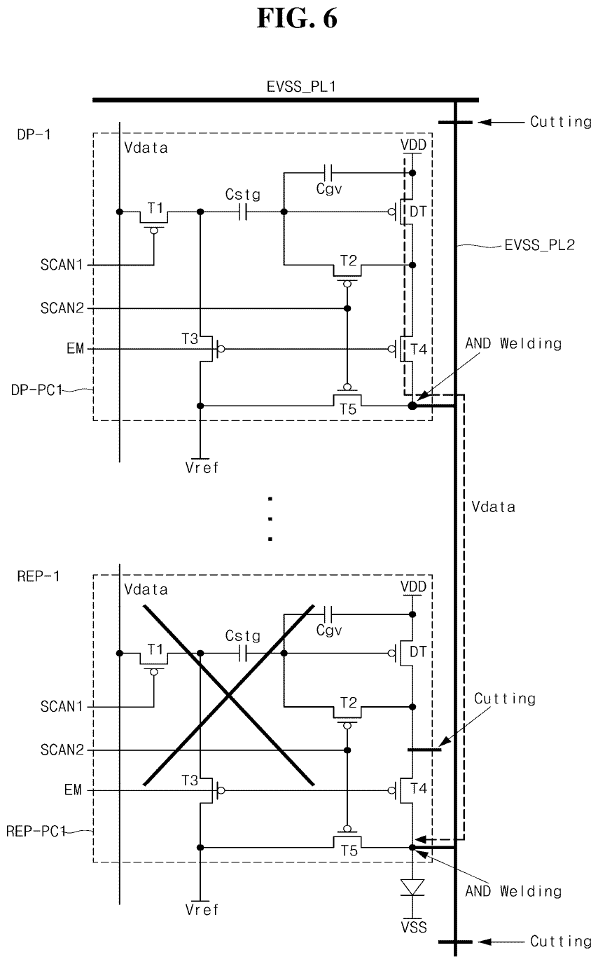

FIG. 6 is a drawing for describing a first dummy pixel DP-1 of a display device and a repair method using the same according to a first embodiment of the present disclosure. Referring to FIG. 6, when a first repair pixel REP-1 is located at a first distance d1 that is relatively close to the first dummy pixel DP-1, the first dummy pixel DP-1 and the first repair pixel REP-1 may have the same or substantially same circuit configuration.

The first dummy pixel DP-1 and the first repair pixel REP-1 spaced apart from each other by the first distance in the first direction may be connected to each other through the low-potential voltage internalized wire EVSS_PL2 that extends in the first direction in an adjacent region. When an upper region and a lower region of the low-potential voltage internalized wire EVSS_PL2 that extends in the first direction are cut, the low-potential voltage internalized wire EVSS_PL2 in the pixel area is electrically isolated from the upper low-potential voltage supply wire EVSS_PL1 and the lower low-potential voltage supply wire EVSS_PL1′.

When anode connection of the first dummy pixel DP-1 is welded (AND Welded) to the electrically isolated low-potential voltage internalized wire EVSS_PL2, a pixel circuit of the first dummy pixel DP-1 and the low-potential voltage internalized wire EVSS_PL2 are electrically interconnected. Accordingly, a driving current generated in the pixel circuit of the first dummy pixel DP-1 may be applied to the low-potential voltage internalized wire EVSS_PL2.

When a connection line between the anode of the light emitting diode OLED and the driving transistor DT in the first repair pixel REP-1 is cut, the pixel circuit of the first repair pixel REP-1 and the light emitting diode OLED may be electrically isolated from each other. By welding (AND Welding) the anode of the light emitting diode OLED of the first repair pixel REP-1 to the low-voltage internalized wire EVSS_PL2, the pixel circuit of the first dummy pixel DP-1 and the light emitting diode OLED of the first repair pixel REP-1 may be electrically interconnected.

Thereafter, when the same or substantially same data voltage as a data voltage input to the first repair pixel REP-1 is input to the first dummy pixel DP-1, the pixel circuit of the first dummy pixel DP-1 may generate a driving current according to the corresponding data voltage, the driving current may be supplied to the light emitting diode OLED of the first repair pixel REP-1. Accordingly, the light emitting diode OLED of the first repair pixel REP-1 may emit light according to the target data voltage.

In the repair method according to the first embodiment, a circuit configuration of the first dummy pixel DP-1 may be the same or substantially same as that of the first repair pixel REP-1 that is a target of repair. Therefore, when a capacitor increase level according to the distance from the first dummy pixel DP-1 to the first repair pixel REP-1 is at a level that does not hinder the light emitting characteristics of the first repair pixel REP-1, the repair method according to the first embodiment may be applied.

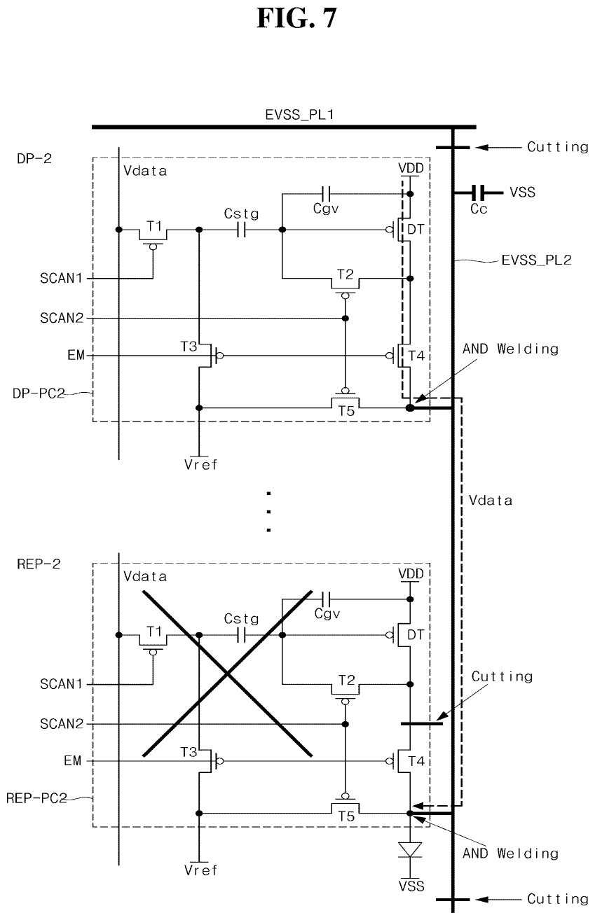

FIG. 7 is a diagram for describing a dummy pixel of a display device and a repair method using the same according to a second embodiment of the present disclosure.

In a second dummy pixel DP-2 of the display device and the repair method using the same according to the second embodiment, a repair method of connecting the second dummy pixel DP-2 and a second repair pixel REP-2 with the low-potential voltage internalized wire EVSS_PL2 may be applied in the same or substantially same manner. That is, each of an anode connection terminal of the second dummy pixel DP-2 and an anode connection terminal of the light emitting diode OLED of the second repair pixel REP-2 may be welded to the electrically isolated low-potential voltage internalized wire EVSS_PL2 to electrically interconnect the pixel circuit of the second dummy pixel DP-2 and the light emitting diode OLED of the second repair pixel REP-2.

When the second repair pixel REP-2 is spaced apart from the second dummy pixel DP-2 by a predetermined distance or more, wiring resistance and capacitance may increase, so that capacitance of the anode of the second repair pixel REP-2 may increase. As a result, even when the same or substantially same data voltage is input, a luminance deviation may occur in the second repair pixel REP-2.

The display device according to the second embodiment of the present disclosure may add a compensation capacitor Cc to the low-potential voltage internalized wire EVSS_PL2 in order to compensate for the capacitance weighted on the anode of the second repair pixel REP-2. The compensation capacitor Cc may have a first electrode connected to the low-potential voltage internalized wire EVSS_PL2 and a second electrode connected to the low-potential driving voltage. Accordingly, capacitance of the low-voltage internalized wire EVSS_PL2 connected from a welding point of the second dummy pixel DP-2 to a welding point of the second repair pixel REP-2 is reduced according to capacitance of the compensation capacitor Cc, so that the capacitance weighted on the anode of the second repair pixel REP-2 may be compensated. Accordingly, the capacitance of the compensation capacitor is adjusted according to a separation distance between the second dummy pixel DP-2 and the second repair pixel REP-2, so that occurrence of a luminance deviation in the second repair pixel REP-2 may be reduced or prevented.

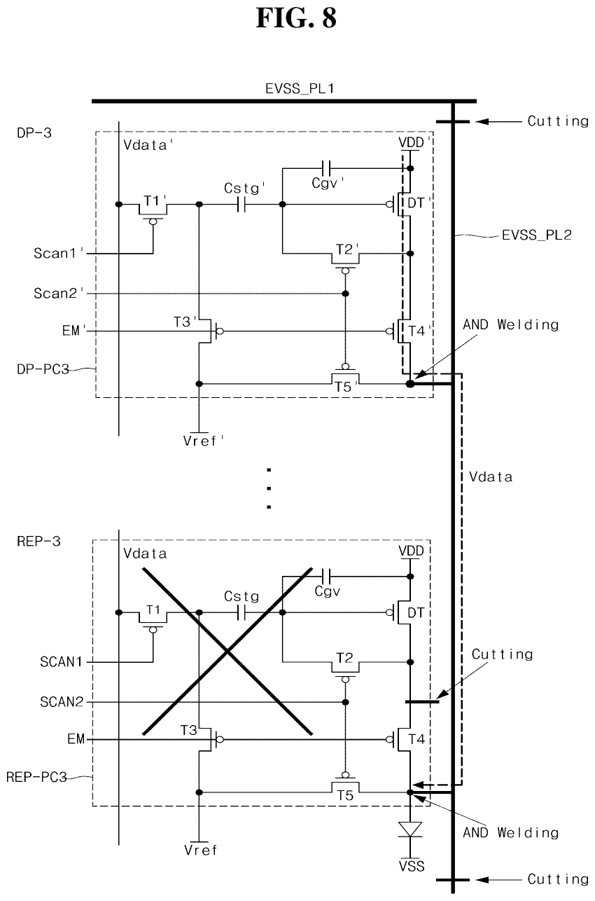

FIG. 8 is a diagram for describing a third dummy pixel DP-3 of a display device and a repair method using the same according to a third embodiment of the present disclosure.

A repair method of connecting the third dummy pixel DP-3 and a third repair pixel REP-3 with the low-potential voltage internalized wire EVSS_PL2 may be applied in the same or substantially same manner as the repair methods of the first and second embodiments. That is, each of an anode connection terminal of a third dummy pixel DP-2 and an anode connection terminal of a light emitting diode OLED of the third repair pixel REP-3 may be welded to the electrically isolated low-potential voltage internalized wire EVSS_PL2, so that a pixel circuit of the third dummy pixel DP-3 and the light emitting diode OLED of the third repair pixel REP-3 may be electrically interconnected.

When the third repair pixel REP-3 is spaced apart from the third dummy pixel DP-3 by a predetermined distance or more, wiring resistance and capacitance may increase, so that capacitance of an anode of the third repair pixel REP-3 may increase. As a result, even when the same data voltage is input, a luminance deviation may occur in the third repair pixel REP-3.

In the display device according to the third embodiment of the present disclosure, in order to compensate for a luminance deviation of the third repair pixel REP-3 according to a third distance d3, a design value of the pixel circuit of the third dummy pixel DP-3 may be changed so that the pixel circuit of the third dummy pixel DP-3 generates a driving current capable of compensating for the luminance deviation in the third repair pixel REP-3. That is, when the same or substantially same data voltage as a data voltage set for light emission of the third repair pixel REP-3 is input to the third dummy pixel DP-3, a design value of the third dummy pixel DP-3 may be set to generate a driving current capable of compensating for the luminance deviation of the third repair pixel REP-3. For example, a channel width, a length, etc. of a driving transistor DT′ of the third dummy pixel DP-3 may be changed, and capacitance of a capacitor Cstg′ may be adjusted. Accordingly, when the same or substantially same data voltage as a data voltage set for the third repair pixel REP-3 is input to the third dummy pixel DP-3, the third dummy pixel DP-3 may generate a compensated driving current capable of compensating for the luminance deviation of the third repair pixel REP-3.

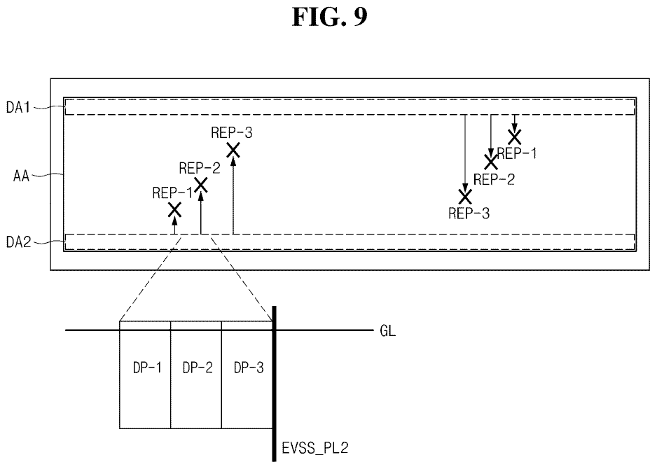

FIG. 9 is an exemplary diagram for describing a structure of the dummy area DA of the display device according to an embodiment of the present disclosure.

According to an embodiment of the present disclosure, a display panel may have a first dummy area DA1 formed on the upper side of the active area AA and a second dummy area DA2 formed on the lower side thereof.

In each of the dummy areas D1 and D2, the first to third dummy pixels DP-1, DP-2, and DP-3 illustrated in FIGS. 6 and 7 may be formed so as to compensate for a luminance deviation according to a distance from the repair pixels REP-1, REP-2, and REP3.

The first to third dummy pixels DP-1, DP-2, and DP-3 may be selected according to the distance from the repair pixels REP-1, REP-2, and REP3 and may be connected to the corresponding repair pixels through the low-voltage internalized wire EVSS_PL2. The first to third dummy pixels DP-1, DP-2, and DP-3 may be connected to the low-voltage internalized wire EVSS_PL2 by welding an anode to the low-voltage internalized wire EVSS_PL2 or by welding a gate line wire GL formed in a horizontal direction thereto, depending on the positions. Since horizontal welding is known technology, a detailed description thereof will be omitted.

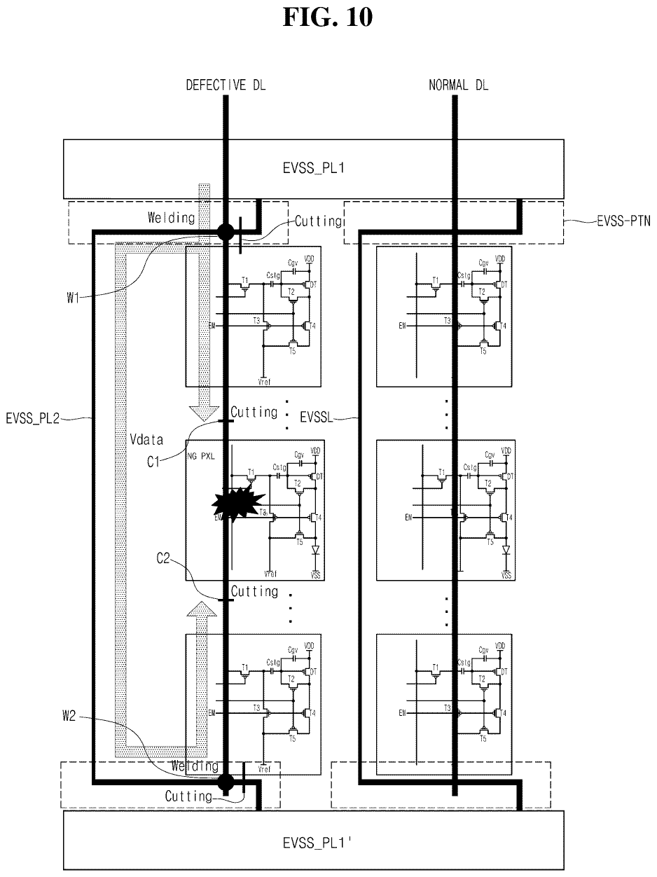

FIG. 10 is a diagram illustrating a pattern of the low-voltage internalized wire EVSS_PL2 of the display device according to an embodiment of the present disclosure.

In the embodiment of the present disclosure, the low-potential voltage internalized wire EVSS_PL2 used as a repair wire may be formed to extend in the first direction from the display panel. In addition to the low-potential voltage internalized wire EVSS_PL2, signal lines of pixels such as data lines DL are formed in the first direction on the display panel. Accordingly, when a pattern portion EVSS-PTN extending in the second direction is formed at uppermost and lowermost portions of the low-potential voltage internalized wire EVSS_PL2, a signal line of the pixel extending in the first direction may be arranged to intersect with the pattern portion EVSS-PTN. Accordingly, when repair is required for the signal line of the pixel extending in the first direction, repair may be easily performed by welding an intersection of the pattern portion EVSS-PTN and the corresponding signal line, and cutting a connection line of the low-potential voltage supply wire EVSS_PL1 and the lower low-potential voltage supply wire EVSS_PL1′.

For example, as shown in FIG. 10, when a defect occurs in the data line DL, a first cutting point C1 and a second cutting point C2 are cut so that a defective portion is electrically isolated. Thereafter, an intersection point of the corresponding data line DL and the upper pattern portion EVSS-PTN is welded as a first welding point W1, and a connection line with the upper low-potential voltage supply wire EVSS_PL1 is cut. An intersection point of the corresponding data line DL and the lower pattern portion EVSS-PTN may be welded as a second welding point W2, and a connection line with the lower low-potential voltage supply wire EVSS_PL1′ may be cut. Accordingly, a signal input to the data line DL may be branched from the first welding point W1 to the remaining data line DL and the low-potential voltage internalized wire EVSS_PL2.

The corresponding pixels may receive a data voltage Vdata through the data line DL connected from the first welding point W1 to the first cutting point C1.

The data voltage Vdata branched from the first welding point W1 to the low-potential voltage internalized wire EVSS_PL2 may be supplied to the data line DL connected to the second cutting point C2 through the second welding point W2. Accordingly, the corresponding pixels may receive the data voltage Vdata through the data line DL connected from the second welding point W2 to the second cutting point C2.

As described above, when a defect occurs in the data line DL and the data voltage Vdata cannot be supplied to a specific section, the defect occurring in the data line DL may be repaired by applying the data voltage Vdata through the low-potential voltage internalized wire EVSS_PL2.

The display device and the method of repairing the same according to the embodiment of the present disclosure may improve production yield and quality deterioration by repairing a defective subpixel.

The display device and the method of repairing the same according to the embodiment of the present disclosure may repair a defective pixel by using a dummy pixel and a low-potential voltage supply wire internalized in a substrate, thereby repairing a subpixel by cutting or welding an existing wire without adding a repair wire.

The display device and the method of repairing the same according to the embodiment of the present disclosure may improve quality deterioration by compensating for a current-voltage curve I-V curve of repaired pixels by repairing using a dummy pixel having suitable electrical characteristics according to a distance between the dummy pixel for repair and a defective pixel to be repaired.

The effects of the present disclosure are not limited to those illustrated above, and the present disclosure encompasses a wider variety of effects.

Even though the embodiments of the present disclosure have been described in more detail with reference to the attached drawings, the present disclosure is not necessarily limited to these embodiments, and various modifications may be made without departing from the technical idea of the present disclosure. Accordingly, the embodiments disclosed in the present disclosure are not intended to limit the technical idea of the present disclosure but to describe the technical idea, and the scope of the technical idea of the present disclosure is not limited by these embodiments. Therefore, it should be understood that the embodiments described above are illustrative and not restrictive in all respects. The scope of protection of the present disclosure should be interpreted by the claims, and all technical ideas within a scope equivalent thereto should be interpreted as being included in the scope of rights of the present disclosure.

What is claimed is:

1. A display device comprising:
a plurality of light emitting pixels provided in a light emitting region of a display panel and including a light emitting element and a light emitting pixel circuit for driving the light emitting element; and
a plurality of dummy pixels provided in a dummy area around the light emitting region and including a dummy pixel circuit and a dummy light emitting element, the dummy pixel circuit configured to generate a driving current by receiving a data voltage supplied to a defective pixel among the light emitting pixels, and the dummy pixels configured to supply the generated driving current to a light emitting element of the defective pixel,
wherein the plurality of dummy pixels comprises a long-distance compensation dummy pixel including a compensation structure that compensates for capacitance according to a separation distance from the defective pixel when the separation distance is greater than a reference distance.

2. The display device according to claim 1, further comprising a first dummy pixel that is connected when the separation distance from the defective pixel is less than or equal to the reference distance,
wherein the first dummy pixel comprises a dummy pixel circuit having the same circuit configuration as a circuit configuration of the light emitting pixel circuit.

3. The display device according to claim 1, wherein:
the dummy pixel circuit of the long-distance compensation dummy pixel comprises a capacitor in which the data voltage is stored, and a driving transistor configured to generate the driving current according to the data voltage stored in the capacitor, and
the driving transistor of the long-distance compensation dummy pixel generates a driving current greater than a driving current generated by the light emitting pixel circuit.

4. The display device according to claim 3, wherein at least one of a channel width or a channel length of the driving transistor of the long-distance compensation dummy pixel is different from a channel width or a channel length of a driving transistor included in the light emitting pixel circuit.

5. The display device according to claim 1, comprising:
a first low-potential voltage supply wire formed to extend in a second direction in an upper region of the display panel;
a second low-potential voltage supply wire formed to extend in the second direction in a lower region of the display panel; and
a plurality of low-potential voltage internalized wires formed by extending in a first direction in the light emitting region and the dummy area, each of the low-potential voltage internalized wires having one end connected to the first low-potential voltage supply wire and the other end connected to the second low-potential voltage supply wire,
wherein any one of the plurality of low-potential voltage internalized wires is electrically separated from the first low-potential voltage supply wire and the second low-potential voltage supply wire and used as a repair wire that electrically interconnects the defective pixel and the dummy pixel.

6. The display device according to claim 5, wherein the repair wire has one end to which an anode of the dummy pixel is connected and the other end to which an anode of the defective pixel is connected.

7. The display device according to claim 5, further comprising a compensation capacitor having a first electrode connected to the repair wire and a second electrode connected to a low-potential voltage.

8. The display device according to claim 7, wherein the compensation capacitor has capacitance set according to a distance between the dummy pixel and the defective pixel.

9. The display device according to claim 5, wherein the plurality of low-potential voltage internalized wires are disposed in the same direction as a plurality of data lines that transmit the data voltage.

10. The display device according to claim 9, wherein the plurality of low-potential voltage internalized wires includes at least one cutting point.

11. The display device according to claim 10, wherein a wire that includes the at least one cutting point among the plurality of low-potential voltage internalized wires is provided with the driving current.

12. A method of repairing the display device according to claim 1, the method comprising connecting the long-distance compensation dummy pixel when a separation distance from the defective pixel is long.

13. The method according to claim 12, wherein:
the display device comprises a first low-potential voltage supply wire formed to extend in a second direction in an upper region of the display panel; a second low-potential voltage supply wire formed to extend in the second direction in a lower region of the display panel; and a plurality of low-potential voltage internalized wires formed by extending in a first direction in the light emitting region and the dummy area, each of the low-potential voltage internalized wires having one end connected to the first low-potential voltage supply wire and the other end connected to the second low-potential voltage supply wire, and
the method further comprises:
preparing a repair wire by electrically isolating one of the low-potential voltage internalized wires adjacent to the defective pixel from the first low-potential voltage supply wire and the second low-potential voltage supply wire;
connecting one end of the repair wire to an anode of a dummy pixel; and
connecting the other end of the repair wire to an anode of the defective pixel.

14. The method according to claim 13, wherein the display device further comprises a compensation capacitor having a first electrode connected to the repair wire and a second electrode connected to a low-potential voltage.

15. The method according to claim 12, wherein at least one of a channel width or a channel length of a driving transistor of the long-distance compensation dummy pixel is different from a channel width or a channel length of a driving transistor included in the light emitting pixel circuit.
